(19) United States
(12) Patent Application Publication
(10) Pub. No.: US 2025/0183145 A1
(43) Pub. Date: Jun. 5, 2025

(54) COMBINED FRONTSIDE/BACKSIDE POWER SUPPLY FOR CHARGE SHARING

(71) Applicant: International Business Machines Corporation, Armonk, NY (US)

(72) Inventors: Nicholas Anthony Lanzillo, Wynantskill, NY (US); Albert M. Chu, Nashua, NH (US); Brent A. Anderson, Jericho, VT (US); Lawrence A. Clevenger, Saratoga Springs, NY (US); Ruilong Xie, Niskayuna, NY (US); Reinaldo Vega, Mahopac, NY (US)

(21) Appl. No.: 18/528,879

(22) Filed: Dec. 5, 2023

(51) Int. Cl. H01L 23/498; H01L 23/00; H01L 25/065

(52) U.S. Cl. CPC H01L 23/49838; H01L 24/16; H01L 24/32; H01L 25/0652; H01L 2224/16146; H01L 2224/16235; H01L 2224/32165; H01L 2224/32225; H01L 2924/1306

(57) ABSTRACT

Embodiments of the invention include a method for fabricating a semiconductor structure and the resulting structure. A plurality of semiconductor devices is formed, including a first semiconductor device and a second semiconductor device. A first contact is formed, where the first contact contacts: (i) the first semiconductor device and (ii) the second semiconductor device. A second contact and a third contact are formed, where the second contact contacts the first semiconductor device and the third contact contacts the second semiconductor device.

### BACKGROUND

The present invention relates generally to the field of semiconductor devices and fabrication, and more particularly to a contact that is connected to two or more devices that is able to prove current to one device through another device that is in an off state.

A field-effect transistor (FET) is a type of transistor that uses an electric field to control the flow of current in a semiconductor. A FET includes three terminals, a source, gate, and drain. FETs control the flow of current by the application of a voltage to the gate, which in turn alters conductivity between the drain and source.

A power delivery network is designed to provide power supply and reference voltage to active devices. Traditionally, this is realized as a network of low-resistive metal wires fabricated through back end of line (BEOL) processing on the frontside of a wafer. A backside power delivery network (BPDN) moves the power distribution network to the backside of the wafer and enables direct power delivery through wider, less resistive metal lines, without electrons needing to travel through a complex BEOL stack.

A buried power rail (BPR) or backside power rail (BSPR) is a metal line construct buried below transistors, partially within a substrate and partially within a shallow trench isolation (STI) layer. Such a power rail takes the role of power rails that have traditionally been implemented at the BEOL level.

### SUMMARY

Embodiments of the invention include a semiconductor structure that includes a plurality of semiconductor devices, including a first semiconductor device and a second semiconductor device. A first contact contacts: (i) the first semiconductor device and (ii) the second semiconductor device. A second contact contacts the first semiconductor device. A third contact contacts the second semiconductor device.

Embodiments of the invention include a method for fabricating a semiconductor structure. The method includes forming a plurality of semiconductor devices, including a first semiconductor device and a second semiconductor device. The method also includes forming a first contact, where the first contact contacts: (i) the first semiconductor device and (ii) the second semiconductor device. The method also includes forming a second contact and a third contact, where the second contact contacts the first semiconductor device and the third contact contacts the second semiconductor device.

Embodiments of the invention also include a method that includes providing a semiconductor structure where the semiconductor structure includes a plurality of semiconductor devices, a first contact contacting each of the plurality of semiconductor devices, a second contact contacting a first semiconductor device of the plurality of semiconductor devices, and a third contact contacting a second semiconductor device of the plurality of semiconductor devices. The method also includes providing, by a power delivery network, electric current through the second contact and the third contact.

### BRIEF DESCRIPTION OF THE DRAWINGS

FIG. 1 depicts a cross-sectional view after the formation of semiconductor devices, in accordance with an embodiment of the present invention.

FIG. 2 depicts a cross-sectional view of a process of forming a contact, in accordance with an embodiment of the present invention.

FIG. 3 depicts a cross-sectional view of a process of forming a frontside middle of line (MOL) back end of line (BEOL) interconnect, in accordance with an embodiment of the present invention.

FIG. 4 depicts a cross-sectional view of a process of forming contacts subsequent to a wafer flip, in accordance with an embodiment of the present invention.

FIG. 5 depicts a cross-sectional view of a process of forming a backside BEOL interconnect, in accordance with an embodiment of the present invention.

FIG. 6 depicts a cross-sectional view of an example depicting how current passes through when one device is in an off state, in accordance with an embodiment of the present invention.

FIG. 7 depicts an example use case, in accordance with an embodiment of the present invention.

### DETAILED DESCRIPTION

According to an aspect of the invention, there is provided a semiconductor structure that includes a plurality of semiconductor devices, including a first semiconductor device and a second semiconductor device, a first contact contacting: (i) the first semiconductor device and (ii) the second semiconductor device, a second contact contacting the first semiconductor device, and a third contact contacting the second semiconductor device. This can serve to allow the first contact to pass electric current to another semiconductor device when either the first semiconductor device or the second semiconductor device are in an “off” state.

In embodiments, the semiconductor structure further includes a power delivery network electrically connected to: (i) the second contact and (ii) the third contact. This can serve to allow the second contact and the third contact to pass electric current from the power delivery network.

In embodiments, the semiconductor structure of claim 1, further includes a first power delivery network electrically connected to the second contact and a second power delivery network electrically connected to the third contact. This can serve allow the second contact to pass electric current from the first power delivery network and the third contact to pass electric current from the second power delivery network. In some embodiments the first and second power delivery networks may deliver different levels of electric current.

In embodiments, the second contact contacts the first semiconductor device in a first direction and the third contact contacts the second semiconductor device in the first direction. This can serve to allow for contacts on surfaces of a same direction for the first and second semiconductor devices to, for example, allow each contact to make contact with the same power delivery network.

In embodiments, the first contact contacts the first semiconductor device and the second semiconductor device in a second direction. This can serve to allow for the first contact to be on a different surface than the second and third contacts which may, for example, allow for backside and frontside power deliver to the first and second semiconductor devices.

In embodiments, the second contact and the third contact are each backside contacts. This can serve to provide backside power delivery to the first and second semiconductor devices.

In embodiments, the first contact is a frontside contact. This can serve to provide power sharing through the first contact such that frontside power delivery is provided to the first and/or second semiconductor devices.

In embodiments, the second contact and the third contact are each frontside contacts. This can serve to provide frontside power delivery to the first and second semiconductor.

In embodiments, the first contact is a backside contact. This can serve to provide power sharing through the first contact such that backside power delivery is provided to the first and/or second semiconductor devices.

In embodiments, the first contact is electrically connected to a third semiconductor device through a power rail. This can serve to provide power sharing to another device, such as the third semiconductor device, via the first contact and a power rail.

In embodiments where the second semiconductor device is in an off state, electric current passes from the power delivery network, through the third contact, the second semiconductor device, and the first contact, to the first semiconductor device. This can serve to allow electric current to pass through the second semiconductor device and provide power sharing to the first semiconductor device through the first contact.

In embodiments, electric current passes from the power delivery network, through the second contact, to the first semiconductor device. This can serve to provide access to the power delivery network by the first semiconductor device.

According to an aspect of the invention, there is provided a method to form a plurality of semiconductor devices, including a first semiconductor device and a second semiconductor device, form a first contact, where the first contact contacts: (i) the first semiconductor device and (ii) the second semiconductor device, and form a second contact and a third contact, where the second contact contacts the first semiconductor device and the third contact contacts the second semiconductor device. This can serve to allow the first contact to pass electric current to another semiconductor device when either the first semiconductor device or the second semiconductor device are in an “off” state.

In embodiments, a backside back end of line (BEOL) interconnect is formed. This can serve to provide for necessary backside BEOL interconnects to electronically connect to a backside power delivery network.

In embodiments, a frontside middle of line (MOL) and back end of line (BEOL) interconnect is formed. This can serve to provide for necessary frontside MOL/BEOL interconnects to electronically connect to a frontside power delivery network.

In embodiments, the semiconductor structure is flipped subsequent to forming the first contact and prior to forming the second contact and the third contact. This can serve to create a device with backside power by allowing for fabrication layers to be added to a first side of the device and, subsequent to the flip, a second, formerly bottom side of the device.

In embodiments, the semiconductor structure is flipped subsequent to forming the second contact and the third contact and prior to forming the first contact. This can serve to create a device with frontside power by allowing for fabrication layers to be added to a first side of the device and, subsequent to the flip, a second, formerly bottom side of the device.

According to an aspect of the invention, there is provided a method to provide a semiconductor structure that includes: a plurality of semiconductor devices, a first contact contacting each of the plurality of semiconductor devices, a second contact contacting a first semiconductor device of the plurality of semiconductor devices, and a third contact contacting a second semiconductor device of the plurality of semiconductor devices, and provide, by a power delivery network, electric current through the second contact and the third contact. This can serve to allow the first contact to pass electric current to another semiconductor device when either the first semiconductor device or the second semiconductor device are in an “off” state.

In embodiments, additional electric current is provided to the second semiconductor device by placing the first semiconductor device in an off state such that electric current passes through the first semiconductor device and the first contact from the second contact. This can serve to allow the first contact to pass electric current to another semiconductor device (e.g., at least the second semiconductor device) because the first semiconductor device is in an “off” state.

In embodiments, additional electric current is provided to the first semiconductor device by placing the second semiconductor device in an off state such that electric current passes through the second semiconductor device and the first contact from the third contact. This can serve to allow the first contact to pass electric current to another semiconductor device (e.g., at least the first semiconductor device) because the second semiconductor device is in an “off” state.

Additionally or alternatively, an embodiment may be a semiconductor structure that includes a plurality of semiconductor devices, including a first semiconductor device and a second semiconductor device, a first contact contacting: (i) the first semiconductor device and (ii) the second semiconductor device, a second contact contacting the first semiconductor device, and a third contact contacting the second semiconductor device. This can serve to allow the first contact to pass electric current to another semiconductor device when either the first semiconductor device or the second semiconductor device are in an “off” state. The semiconductor structure further includes a power delivery network electrically connected to: (i) the second contact and (ii) the third contact. The semiconductor structure further includes that where the second semiconductor device is in an off state, electric current passes from the power delivery network, through the third contact, the second semiconductor device, and the first contact, to the first semiconductor device. This can serve to allow the first contact to pass electric current to another semiconductor device when either the first semiconductor device or the second semiconductor device are in an “off” state.

Additionally or alternatively, an embodiment may be a method to form a plurality of semiconductor devices, including a first semiconductor device and a second semiconductor device, form a first contact, where the first contact contacts: (i) the first semiconductor device and (ii) the second semiconductor device, flip the semiconductor structure, form a second contact and a third contact, where the second contact contacts the first semiconductor device and the third contact contacts the second semiconductor device, form a BEOL interconnect, form a MOL/BEOL interconnect. This can serve to create a device that allows the first contact to pass electric current to another semiconductor device when either the first semiconductor device or the second semiconductor device are in an “off” state.

Additionally or alternatively, an embodiment may be a method to provide a semiconductor structure that includes: a plurality of semiconductor devices, a first contact contacting each of the plurality of semiconductor devices, a second contact contacting a first semiconductor device of the plurality of semiconductor devices, and a third contact contacting a second semiconductor device of the plurality of semiconductor devices, provide, by a power delivery network, electric current through the second contact and the third contact, provide additional electric current to the second semiconductor device by placing the first semiconductor device in an off state such that electric current passes through the first semiconductor device and the first contact from the second contact. This can serve to allow the first contact to pass electric current to another semiconductor device (e.g., at least the second semiconductor device) because the first semiconductor device is in an “off” state.

Embodiments of the present invention recognize that semiconductor devices with both front and backside power connections result in improved performance when compared to semiconductor devices that only receive power from a single side.

Embodiments of the present invention describe an approach for fabricating semiconductor devices, the approach including forming a plurality of semiconductor devices. Embodiments of the present invention further describe forming a frontside contact formation that contacts the plurality of semiconductor devices. Embodiments of the present invention further describe forming a frontside middle of line (MOL) and/or back end of line (BEOL) build. Embodiments of the present invention further describe performing a wafer flip and forming backside contact formations, each backside contact formation contacting a single semiconductor device of the plurality of semiconductor devices. Embodiments of the present invention further describe forming a backside BEOL build.

Embodiments of the present invention recognize that, while the topside contact is described herein as contacting the plurality of semiconductor devices, and the backside contacts are described herein as each contacting a single semiconductor device of the plurality of semiconductor devices, in some embodiments, the this may be reversed. For example, in some embodiments, a plurality of topside contacts each contact a single semiconductor device of the plurality of semiconductor devices while a backside contact contacts the plurality of semiconductor devices. Similarly, while only two semiconductor devices are depicted in the figures that depict the fabrication steps, it should be noted that any number of semiconductor devices may be present in embodiments of the present invention.

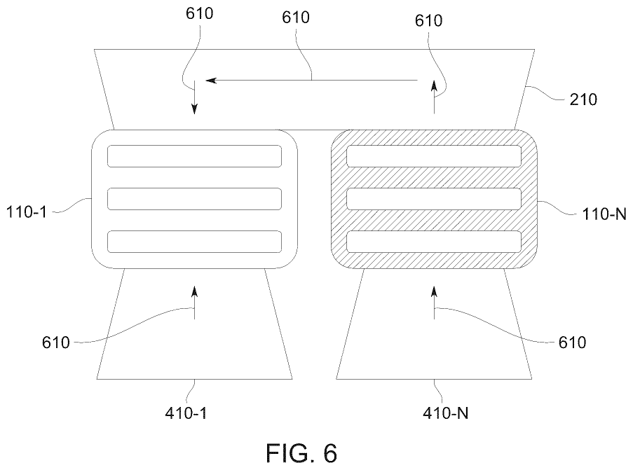

Embodiments of the present invention describe a resulting semiconductor structure that includes at least two semiconductor devices having a first set of contacts in a first direction to a power delivery network. Embodiments of the present invention may further describe that a second contact contacts each of the at least two semiconductor devices in a second direction. It should be noted that in some embodiments of the present invention all of the at least two semiconductor devices are contacted by the second contact. In other embodiments, a subset of the at least two semiconductor devices are contacted by the second contact, where the subset does not include all of the at least two semiconductor devices. Embodiments of the present invention may further describe that the second contact can connect the at least two semiconductor devices in the second direction. Embodiments of the present invention may further describe that the second contact allows semiconductor devices to be supplied current from two directions when another semiconductor device connected to the second contact is in an off state. Such a scenario is described in more detail with reference to FIG. 6.

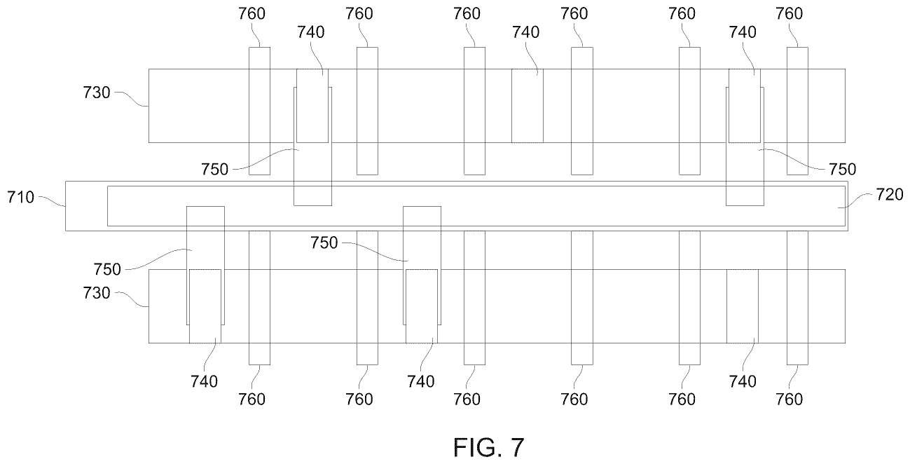

Embodiments of the present invention may further describe that power delivery may be on either the front or backside of each of the semiconductor devices. Embodiments of the present invention may further describe that the second contact can connect two or more semiconductor devices. Embodiments of the present invention may further describe that multiple instances of the second contact may be connected by a power rail. An example embodiment that includes a power rail and multiple instances of a type of contact acting as the second contact described above is described in more detail with reference to FIG. 7.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Each reference number may refer to an item individually or collectively as a group. For example, contacts 410 may refer to an individual contact, such as contact 410-1 or multiple contacts, such as contacts 410-1 through 410-N.

Many of the layers depicted in the Figures are simplified as the specific details of each layer are not integral to embodiments of the invention described herein. For example, semiconductor devices 110-1 through 110-N do not show the specific components that make up each semiconductor device 110 as a variety of devices may be utilized and, ultimately, it is only integral that each device 110 is capable of being in an “off” state and being contacted in two separate directions. For example, semiconductor devices 110 may be transistors such as field-effect transistors (FETs). Semiconductor device 110-1 corresponds to a first semiconductor device. Semiconductor device 110-1 corresponds to a second semiconductor device. Collectively, semiconductor devices 110-1 through 110-N correspond to a plurality of semiconductor devices.

The present invention will now be described in detail with reference to the Figures.

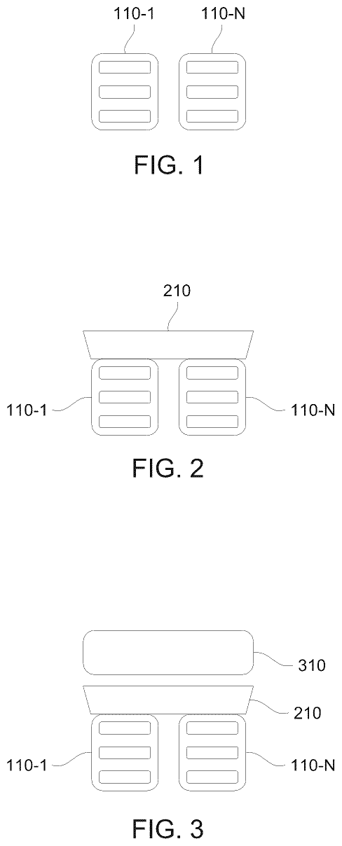

FIG. 1 depicts a cross-sectional view after the formation of semiconductor devices 110-1 through 110-N. In some embodiments, each of semiconductor devices 110-1 through 110-N are the same type of device. In other embodiments, semiconductor devices 110-1 through 110-N may include two or more different types of devices. In general, semiconductor devices 110-1 through 110-N are provided where each semiconductor device 110 has at least two directions from which contacts can be placed to provide an electric current. Further, at least one of semiconductor devices 110-1 through 110-N is capable of being in an “off” state and when in such an “off” state, electric current is able to pass through the respective semiconductor device 110. Semiconductor device 110 may be, for example, a transistor such as a FET, FinFET, gate-all-around (GAA) nanosheet FET, stacked nanosheet transistor, vertical-transport nanosheet FET (VTFET), etc. In some embodiments, semiconductor device 110 may be a memory element, such as, for example, a magnetic tunnel junction (MTJ).

If, for example, the devices 110-1 through 110-N are GAA FETs, a process such as the process described below may be used to create each device 110. It should be noted that the described approach is simply one example and a variety of different types of devices and approaches to fabricate them are contemplated by embodiments of the present invention and could be fabricated according to processes known by one of ordinary skill in the art.

A semiconductor substrate may be provided. Such a semiconductor substrate may be composed of a silicon containing material. Silicon containing materials include, but are not limited to, silicon, single crystal silicon, polycrystalline silicon, SiGe, single crystal SiGe, polycrystalline SiGe, or silicon doped with carbon (C), amorphous silicon, and combinations and multi-layers thereof. The semiconductor substrate can also be composed of other semiconductor materials, such as germanium (Ge), and compound semiconductor substrates, such as type III/V semiconductor substrates, e.g., gallium arsenide (GaAs). In general, the semiconductor substrate is a smooth surface substrate. In some embodiments, the semiconductor substrate can be a partially processed complementary metal-oxide semiconductor (CMOS) integrated wafer with transistors and wiring levels or gate electrodes embedded beneath the surface.

A semiconductor material stack (sacrificial semiconductor material layer, semiconductor channel material layer) is formed upon the semiconductor layer. The semiconductor material stack includes vertically aligned alternating layers of sacrificial semiconductor material and semiconductor channel material. The semiconductor material stack is sequentially formed upon the semiconductor layer. As mentioned above, the semiconductor material stack includes sacrificial semiconductor material layers and semiconductor channel material layers, which alternate one atop the other. Only by way of one example, the semiconductor material stack includes three layers of sacrificial semiconductor material and three layers of semiconductor channel material. The semiconductor material stack is used to provide a gate-all-around device that includes vertically stacked semiconductor channel material nanosheets. It should be noted that while the depicted embodiment uses a nanosheet device, the device can be any kind of non-vertical or horizontal device, such as, for example, fin field-effect transistor (FinFET), planar FET, nanowire, or extremely-thin silicon-on-insulator (ETSOI).

Each sacrificial semiconductor material layer is composed of a first semiconductor material which differs in composition from the semiconductor layer or semiconductor channel material layer. In one embodiment, each sacrificial semiconductor material layer is composed of silicon germanium with Ge % 20% to 35% and the semiconductor channel material layer is composed of silicon. The sacrificial semiconductor material layer and semiconductor channel material layer can be formed utilizing epitaxial growth from the semiconductor layer.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growth of the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

The sacrificial semiconductor material layers that constitute the semiconductor material stack may have a thickness from five nm to twenty nm, while the semiconductor channel material layers that constitute the semiconductor material stack may have a thickness from six nm to twelve nm. Each sacrificial semiconductor material layer may have a thickness that is the same as, or different from, a thickness of each semiconductor channel material layer. In an embodiment, each sacrificial semiconductor material layer has an identical thickness. In an embodiment, each semiconductor channel material layer has an identical thickness.

Following epitaxial growth of the topmost layer of the semiconductor material stack (sacrificial semiconductor material layer, semiconductor channel material layer) a patterning process may be used to provide the semiconductor material stack. Patterning may be achieved by lithography and etching as is well known to those skilled in the art.

A shallow trench isolation (STI) layer may be formed by patterning a hardmask layer (not shown) using lithography and etching such that top surfaces of portions of the semiconductor layer are exposed corresponding to locations where trenches for the STI layer are desired. Accordingly, the hardmask layer is patterned such that the semiconductor layer is exposed at desired trench locations for the STI layer.

Physically exposed portions of the semiconductor layer are removed. The removing of portions of the semiconductor layer can be performed utilizing an anisotropic etching process such as, for example, reactive ion etching (RIE). Portions of the semiconductor layer remain beneath the hardmask.

A sacrificial gate structure may be formed. Each sacrificial gate structure is located on a first side and a second side of the semiconductor material stack (sacrificial semiconductor material layer, semiconductor channel material layer) and spans across a topmost surface of a portion of the semiconductor material stack (sacrificial semiconductor material layer, semiconductor channel material layer). Each sacrificial gate structure thus straddles over a portion of the semiconductor material stack (sacrificial semiconductor material layer, semiconductor channel material layer).

Each sacrificial gate structure may include a single sacrificial material portion or a stack of two or more sacrificial material portions (i.e., at least one sacrificial material portion). In one embodiment, the at least one sacrificial material portion comprises, from bottom to top, a sacrificial gate layer portion and a sacrificial dielectric cap portion. In some embodiments, the sacrificial dielectric cap portion can be omitted and only a sacrificial gate layer portion is formed. The at least one sacrificial material portion can be formed by forming a blanket layer (or layers) of a material (or various materials) and then patterning the material (or various materials) by lithography and an etch. In one embodiment, the at least one sacrificial material portion can be formed by first depositing a blanket layer of a sacrificial gate material. The sacrificial gate material can include any material including, for example, polysilicon, amorphous silicon, an elemental metal (e.g., tungsten, titanium, tantalum, aluminum, nickel, ruthenium, palladium and platinum), an alloy of at least two elemental metals or multilayered combinations thereof. The sacrificial gate material 320 can be formed utilizing a deposition process including, for example, chemical vapor deposition (CVD), plasma enhanced chemical vapor deposition (PECVD), physical vapor deposition (PVD), sputtering, atomic layer deposition (ALD) or other like deposition processes.

After forming the blanket layer of sacrificial gate material, a blanket layer of a sacrificial gate cap material can be formed. The sacrificial gate cap material may include a hardmask material such as, for example, silicon dioxide and/or silicon nitride. The sacrificial gate cap material can be formed by any suitable deposition process such as, for example, chemical vapor deposition (CVD) or plasma enhanced chemical vapor deposition (PECVD).

After providing the above mentioned sacrificial material stack (or any subset of the sacrificial materials), lithography and etching can be used to pattern the sacrificial material stack (or any subset of the sacrificial materials) and to provide the at least one sacrificial gate structure. The remaining portions of the sacrificial gate material constitute a sacrificial gate layer portion, and the remaining portions of the sacrificial dielectric cap material constitute a sacrificial dielectric cap portion.

After providing the sacrificial gate structure and the sacrificial dielectric cap, dielectric spacer material layer can be formed on exposed surfaces of each sacrificial gate structure and each sacrificial dielectric cap. The dielectric spacer material layer can be formed by first providing a dielectric spacer material and then etching the dielectric spacer material. One example of a dielectric spacer material that may be employed in the present application is silicon nitride. In general, the dielectric spacer material layer comprises any dielectric spacer material, including, for example, a dielectric nitride, dielectric oxide, and/or dielectric oxynitride. More specifically, the dielectric spacer material layer may be, for example, SiBCN, SiBN, SiOCN, SiON, SiCO, or SiC. In one example, the dielectric spacer material layer is composed of a dielectric material such as SiO₂.

The dielectric spacer material that provides the dielectric spacer material layer may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Recesses may be formed within the semiconductor material stack, creating the formation of nanosheet stacks of alternating nanosheets of sacrificial semiconductor material layers and semiconductor channel material layers that are under at least one sacrificial gate structure and dielectric spacer material layer.

The nanosheet stack is formed by removing physically exposed portions of the semiconductor material stack (sacrificial semiconductor material layer, semiconductor channel material layer) and portions of semiconductor layer that are not protected by the least one sacrificial gate structure and the dielectric spacer material layer. In general, each recess may include the eventual location of sidewall spacer, etch stop layer, buffer layer, and source/drain region, for the semiconductor device.

The removing of the portions of the semiconductor material stack (sacrificial semiconductor material layer, semiconductor channel material layer) and the portions of semiconductor layer not covered by the least one sacrificial gate structure and the dielectric spacer material layer can be performed utilizing an anisotropic etching process such as, for example, reactive ion etching (RIE). Portions of the semiconductor material stack (sacrificial semiconductor material layer, semiconductor channel material layer) remain beneath at least one sacrificial gate structure and the dielectric spacer material layer. The remaining portion of the semiconductor material stack that is present beneath the at least one sacrificial gate structure and the dielectric spacer material layer is referred to as a nanosheet stack.

Each nanosheet stack includes alternating nanosheets of remaining portions of each sacrificial semiconductor material layer and remaining portions of each semiconductor channel material layer. Each nanosheet (i.e., sacrificial semiconductor material layer 240 or semiconductor channel material layer) that constitutes the nanosheet stack has a thickness as mentioned above for the individual sacrificial semiconductor material layers and semiconductor channel material layers, and a width from thirty nm to two hundred nm. In some embodiments, the sidewalls of each sacrificial semiconductor material layer are vertically aligned to sidewalls of each semiconductor channel material layer, and the vertically aligned sidewalls of the nanosheet stack are vertically aligned to an outmost sidewall of the dielectric spacer material layer.

The sacrificial semiconductor material layer is recessed and inner spacer is formed. Each recessed sacrificial semiconductor material layer has a width that is less than the original width of each sacrificial semiconductor material layer. The recessing of each sacrificial semiconductor material layer provides a gap between each neighboring pair of semiconductor channel material layer within a given nanosheet stack. The recessing of each sacrificial semiconductor material layer may be performed utilizing a lateral etching process that is selective in removing physically exposed end portions of each sacrificial semiconductor material layer relative to each semiconductor channel material layer.

The additional dielectric spacer material that is added can be compositionally the same as the dielectric spacer material layer mentioned above. In one example, the additional dielectric spacer material and the dielectric spacer material layer are both composed of silicon nitride. For clarity, the additional dielectric spacer material and the dielectric spacer material layer can now be collectively referred to as inner spacer. The inner spacer is formed by a conformal dielectric liner deposition followed by isotropic etching back the deposited liner.

Sidewall spacers can be formed on exposed sidewalls of each semiconductor layer, each inner spacer, each semiconductor channel material layer, and each dielectric spacer material layer. In some embodiments, sidewall spacers are formed such that upper portions of dielectric spacer material layer remain exposed. Sidewall spacers can be formed by first providing a dielectric spacer material and then etching the dielectric spacer material. One example of a dielectric spacer material that may be employed in the present application is silicon nitride (SiN). In general, sidewall spacers comprise any dielectric spacer material, including, for example, a dielectric nitride, dielectric oxide, and/or dielectric oxynitride. More specifically, sidewall spacers may be, for example, SiBCN, SiBN, SiOCN, SION, SiCO, or SiC. In one example, sidewall spacers are composed of a dielectric material such as SiO₂.

The dielectric spacer material that provides sidewall spacers may be provided by a deposition process including, for example, ALD, chemical vapor deposition (CVD), plasma enhanced chemical vapor deposition (PECVD), or physical vapor deposition (PVD). The etch used to provide the dielectric spacer material layer may comprise a dry etching process such as, for example, reactive ion etching.

Exposed portions of sidewall spacers may be removed by an etching process, such as RIE, wet etch, or any etch process which can be used to selectively etch sidewall spacers.

Source/drain regions are formed by epitaxial growth of a semiconductor material on physically exposed sidewalls of each semiconductor channel material layer.

Each source/drain region includes a semiconductor material and a dopant. The semiconductor material that provides each source/drain region can be selected from one of the semiconductor materials mentioned above for the semiconductor substrate. In some embodiments, the semiconductor material that provides each source/drain region may comprise a same semiconductor material as that which provides the semiconductor channel material layer. In other embodiments, the semiconductor material that provides each source/drain region may comprise a different semiconductor material than that which provides the semiconductor channel material layer. For example, the semiconductor material that provides each source/drain region may comprise a silicon germanium alloy, while the semiconductor channel material layer may comprise silicon.

The dopant that is present in each source/drain region can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one embodiment, the dopant that can be present in each source/drain region can be introduced into the precursor gas that provides each source/drain region. In another embodiment, the dopant can be introduced into an intrinsic semiconductor layer by utilizing one of ion implantation or gas phase doping. In one example, each source/drain region comprises a silicon germanium alloy that is doped with a p-type dopant such as, for example, boron. As mentioned above, each source/drain region is formed by an epitaxial growth (or deposition) process, as is defined above.

ILD material may be formed above and around each source/drain region. ILD material may be composed of silicon dioxide, undoped silicate glass (USG), fluorosilicate glass (FSG), borophosphosilicate glass (BPSG), a spin-on low-K dielectric layer, a chemical vapor deposition (CVD) low-K dielectric layer or any combination thereof. The term “low-K” as used throughout the present application denotes a dielectric material that has a dielectric constant of less than silicon dioxide. In another embodiment, a self-planarizing material such as a spin-on glass (SOG) or a spin-on low-K dielectric material such as SiLK™ can be used as the ILD material. The use of a self-planarizing dielectric material as the ILD material may avoid the need to perform a subsequent planarizing step.

In one embodiment, the ILD material can be formed utilizing a deposition process including, for example, CVD, plasma enhanced chemical vapor deposition (PECVD), evaporation or spin-on coating. In some embodiments, particularly when non-self-planarizing dielectric materials are used as the ILD material, a planarization process, such as CMP, or an etch back process follows the deposition of the dielectric material that provides the ILD material. The ILD material may be present atop each source/drain region.

Each sacrificial gate structure (i.e., sacrificial gate structure and sacrificial dielectric cap) is removed to provide a gate cavity for the FET.

Next, each semiconductor channel material nanosheet (i.e., semiconductor channel material layer) of the FET is suspended by selectively etching each recessed sacrificial semiconductor material nanosheet (i.e., sacrificial semiconductor material layer relative to each semiconductor channel material nanosheet (i.e., semiconductor channel material layer).

Functional gate structures are formed in each gate cavity. The functional gate structure surrounds a physically exposed surface of each semiconductor channel material nanosheet (i.e., semiconductor channel material layer). By “functional gate structure” it is meant a permanent gate structure used to control output current (i.e., flow of carriers in the channel) of a semiconducting device through electrical or magnetic fields.

In some embodiments, a gate dielectric portion may be present that includes a gate dielectric material. Such a gate dielectric portion may be an oxide, nitride, and/or oxynitride. In one example, the gate dielectric portion can be a high-k material having a dielectric constant greater than silicon dioxide. Example high-K dielectrics include, but are not limited to, HfO2, ZrO2, La2O3, Al2O3, TiO2, SrTiO3, LaAlO3, Y2O3, HfOxNy, ZrOxNy, La2OxNy, Al2OxNy, TiOxNy, SrTiOxNy, LaAlOxNy, Y2OxNy, SiON, SiNx, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-k gate dielectric, can be formed and used as the gate dielectric portion.

The gate dielectric material used in providing a gate dielectric portion can be formed by any deposition process including, for example, chemical vapor deposition (CVD), plasma enhanced chemical vapor deposition (PECVD), physical vapor deposition (PVD), sputtering, or atomic layer deposition. In one embodiment of the present application, the gate dielectric material used in providing a gate dielectric portion can have a thickness in a range from one nm to ten nm. Other thicknesses that are lesser than, or greater than, the aforementioned thickness range can also be employed for the gate dielectric material that may provide a gate dielectric portion.

The replacement gate may include a gate conductor material and a gate dielectric. The gate conductor material used in providing the replacement gate can include any conductive material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride, TiAlC, TiC, TiAl), an elemental metal silicide (e.g., tungsten silicide, nickel silicide, and titanium silicide), or multilayered combinations thereof. In one embodiment, the replacement gate may comprise an nFET gate metal. In another embodiment, the replacement gate may comprise a pFET gate metal. When multiple gate cavities are formed, it is possible to form a nFET in a first set of the gate cavities and wrapping around some of the semiconductor channel material nanosheet (i.e., semiconductor channel material layer) and a pFET in a second set of the gate cavities and wrapping around some of the semiconductor channel material nanosheet (i.e., semiconductor channel material layer).

The gate conductor material used in providing the replacement gate can be formed utilizing a deposition process including, for example, CVD, plasma enhanced chemical vapor deposition (PECVD), physical vapor deposition (PVD), sputtering, atomic layer deposition (ALD) or other like deposition processes. When a metal silicide is formed, a conventional silicidation process is employed. In one embodiment, the gate conductor material used in providing the replacement gate can have a thickness from five nm to two hundred nm. Other thicknesses that are lesser than, or greater than, the aforementioned thickness range can also be employed for the gate conductor material used in providing the replacement gate.

In some embodiments, a functional gate structure (replacement gate) can be formed by providing a functional gate material stack of the gate dielectric material and the gate conductor material. A planarization process may follow the formation of the functional gate material stack.

Gate cuts may be patterned by conventional lithography and etch processes to isolate the gate regions at cell boundaries. Each gate cut is filled with a dielectric material such as, for example, SiN or a combination of SiN and SiO₂.

In some embodiments, a GAA FET, such as the GAA FET described comprises one or more of the semiconductor devices 110. In other embodiments, other types of devices may comprise each of semiconductor devices 110-1 through 110-N.

FIG. 2 depicts a cross-sectional view of fabrication steps, in accordance with an embodiment of the present invention. FIG. 2 shows the formation of contact 210. Contact 210 corresponds to a first semiconductor device.

While not depicted, one or more trenches may be formed in ILD material by, for example, a lithography and etching process, such as reactive-ion etching (RIE), laser ablation, or any etch process which can be used to selectively remove a portion of material such as ILD material. A hardmask (not shown) may be patterned using photoresist to expose areas of the device where trenches are desired and the hardmask may be utilized during the etching process in the creation of the trenches. For example, placement of contact 210 may be placed so as to opportunistically minimize parasitic capacitance and to minimize block of, for example, M1 tracks. The etching process only removes portions of the device not protected by the hardmask and the etching process stops at, for example, a source/drain region and/or gate region of semiconductor devices 110-1 through 110-N.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

In general, contact 210 is formed and makes contact with a plurality of semiconductor devices 110. Contact 210 may also be referred to as a redundant contact and contacts two or more of semiconductor devices 110 such that contact 210 allows a first device, such as semiconductor device 110-1 to be supplied current through a second device, such as semiconductor device 110-N, when semiconductor device 110-N is in an “off” state. In some embodiments, such embodiments depicted in FIGS. 2-5, contact 210 is a frontside contact. In other embodiments, contact 210 may be a backside contact.

Contact 210 may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Contact 210 can be formed utilizing a deposition process including, for example, CVD, PECVD, physical vapor deposition (PVD), sputtering, atomic layer deposition (ALD) or other like deposition processes.

FIG. 3 depicts a cross-sectional view of fabrication steps, in accordance with an embodiment of the present invention. FIG. 3 shows the formation of frontside MOL/BEOL interconnect 310.

Frontside MOL/BEOL interconnect 310 is depicted as a simple layer, rather than showing the specific interconnects. Frontside MOL/BEOL interconnect 310 may be formed according to processes known in the art such as, for example, patterning and dual damascene.

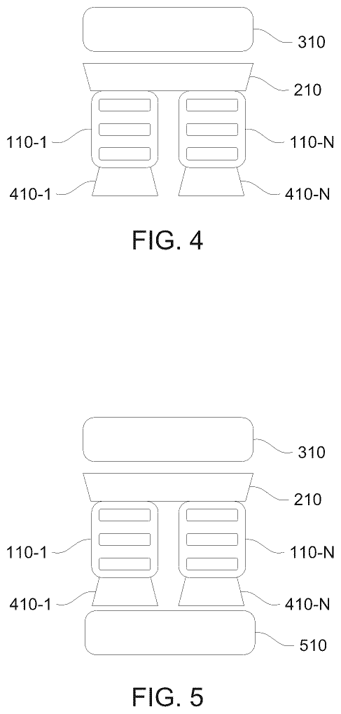

FIG. 4 depicts a cross-sectional view of fabrication steps, in accordance with an embodiment of the present invention. FIG. 4 shows the formation of contacts 410-1 through 410-N subsequent to a wafer flip. Contact 410-1 corresponds to a second contact. Contact 410-N corresponds to a third contact.

A carrier wafer (not shown) is a wafer that is bonded with a top surface of MOL/BEOL interconnect 310. The carrier wafer may be, for example, a silicon wafer. Such bonding can be accomplished using fusion bonding (for example silicon oxide to silicon oxide) or by means of intermediate-layer bonding (for example using adhesives). A variety of bonding means may be used such as, for example, pressure bonding, for press-bonding the device to the carrier wafer or a heat bonding approach for utilizing heat to bond the device to the carrier wafer.

Subsequent to bonding the device to the carrier wafer, the device is flipped upside-down such that the formation or removal of any layers occurs on what is considered to be the bottom of the device. This flip is not depicted in the Figures and, accordingly, FIGS. 4 through 5 depict process steps that occur on the bottom surfaces of the device. In reality, during fabrication, these steps are performed when the device is upside-down, as compared to the depiction of FIGS. 4 through 5.

While not depicted, one or more trenches may be formed in ILD material by, for example, a lithography and etching process, such as reactive-ion etching (RIE), laser ablation, or any etch process which can be used to selectively remove a portion of material such as ILD material. A hardmask (not shown) may be patterned using photoresist to expose areas of the device where trenches are desired and the hardmask may be utilized during the etching process in the creation of the trenches. The etching process only removes portions of the device not protected by the hardmask and the etching process stops at, for example, a source/drain region and/or gate region of semiconductor devices 110-1 through 110-N.

In some embodiments, subsequent to the formation of the trenches, the hardmask is removed. In general, the process of removing the hardmask involves the use of an etching process such as RIE, laser ablation, or any etch process which can be used to selectively remove a portion of material, such as the hardmask. In some embodiments, prior to the removal of the hardmask, the photoresist (not shown) is removed. The process of removing the photoresist is similar to that of the process of removing the hardmask.

In general, contacts 410 are formed and each contact 410 (i.e., each individual contact 410-1 through 410-N) makes contact with a single semiconductor device 110. For example, as depicted in FIG. 4, contact 410-1 makes contact with semiconductor device 110-1 and contact 410-N makes contact with semiconductor device 110-N. In some embodiments, such embodiments depicted in FIGS. 2-5, each contact 410 is a backside contact. In other embodiments, each contact 410 may be a frontside contact.

Contacts 410-1 through 410-N may be formed by metal deposition and planarization. The metal layers comprise a silicide liner, such as, for example, Ti, Ni, or NiPt, followed by adhesion metal liner, such as, for example, TiN, and a conductive metal fill, such as, for example, Co, Ru, W, or Cu.

Contacts 410-1 through 410-N can be formed utilizing a deposition process including, for example, CVD, PECVD, physical vapor deposition (PVD), sputtering, atomic layer deposition (ALD) or other like deposition processes.

FIG. 5 depicts a cross-sectional view of fabrication steps, in accordance with an embodiment of the present invention. FIG. 5 shows the formation of backside BEOL interconnect 510.

Backside BEOL interconnect 510 is depicted as a simple layer, rather than showing the specific interconnects. Backside BEOL interconnect 510 may be formed according to processes known in the art such as, for example, patterning and dual damascene.

FIG. 6 depicts a cross sectional view depicting an example of how current passes through semiconductor device 110-N, when in an “off” state, to provide frontside power to semiconductor device 110-1, in accordance with an embodiment of the present invention.

FIG. 6 depicts an example resulting structure subsequent to the fabrication steps discussed with reference to FIGS. 1 through 5. More particularly, FIG. 6 depicts two semiconductor devices (110-1, 110-N) that make contact with contact 210. Semiconductor device 110-1 also makes contact with contact 410-1 while semiconductor device 110-N makes contact with contact 410-N.

As depicted, contact 410-1 and 410-N are each connected to a power delivery network. In some embodiments, contact 410-1 through contact 410-N are each connected to the same power delivery networks. In other embodiments, one or more of contact 410-1 through contact 410-N are connected to different power delivery networks (e.g., contact 410-1 and contact 410-2 may be connected to a first power delivery network while contacts 410-15 through 410-N are each connected to a second power delivery network). By connecting to multiple power delivery networks, the corresponding voltages that are provided to semiconductor devices 110-1 through 110-N may vary.

FIG. 6 depicts a scenario where semiconductor device 110-N is in an “off” state. By being in an “off state” electric current 610 can travel from contact 410-N, through semiconductor device 110-N and contact 210, so that other devices in contact with contact 210, such as semiconductor device 110-1 can receive electric current 610 at the surface contacting contact 210. In addition, semiconductor device 110-1 can receive electric current 610 from contact 410-1.

While FIG. 6 depicts a scenario where semiconductor device 110-N is in an “off” state, it should be noted that, in the depicted example, if semiconductor devices 110-1 and 110-N are each in an “on” state, electric current 610 would not pass up through the contact 210. If semiconductor device 110-1 was in an “off” state and semiconductor device 110-N was in an “on” state, electric current 610 would pass through contact 210 in an opposite direction (as depicted in FIG. 6), providing electric current 610 to semiconductor devices 110-N.

While FIG. 6 only depicts two semiconductor devices (110-1, 110-N), it should be noted that any number of semiconductor devices 110 may be present and more than two semiconductor devices 110 may share electric current 610 through contact 210. In some embodiments, contact 210 may be connected to other contacts (not shown), by a power rail, resulting in an ability to share electric current with other devices that are connected to contact 210 via the power rail and the other contacts.

FIG. 7 depicts an example use case, in accordance with one embodiment of the present invention.

FIG. 7 depicts M1 level 710. M1 level 710 is the first metal wiring level above a semiconductor substrate. M1 level 710 may include via bar 720 which can provide an electrical connection between two or more layers. FIG. 7 further depicts two active (RX) areas 730. Each RX area 730 is where, for example, source and drain regions of transistors may be formed. In general, semiconductor devices similar to semiconductor devices 110-1 through 110-N may be fabricated within each RX area 730. In the depicted example, contacts 740 may be backside contacts that may comprise direct bonded copper (DBC) substrates. DBS are composed of a ceramic material tile with a sheet of copper bonded to one or both sides by a high-temperature oxidation process. As depicted, some instances of contacts 740 include backside power only, while other instances of contacts 740 below contacts 750 and support charge sharing and redundancy, as described with respect to embodiments of the present invention.

Spacers 760 may be dielectric material including, for example, a dielectric nitride, dielectric oxide, and/or dielectric oxynitride. More specifically, the dielectric spacer material layer may be, for example, SiBCN, SiBN, SiOCN, SiON, SiCO, or SiC. In one example, the dielectric spacer material layer is composed of a dielectric material such as SiO₂. Spacers 760 may be used to electronically isolate each of the semiconductor devices such that they are entirely isolated or, in some instances, only electronically connected via contacts 750 and via bar 720.

Contacts 750 may be frontside contacts and, in the depicted embodiment, enable electric current sharing between multiple semiconductor devices based on their contact with via bar 720. As depicted, contacts 750 contact four separate semiconductor devices which, when one or more of such devices is in an “off” state, would enable electric current to flow from one or more contacts 740 through contacts 750 and via bar 720 to other semiconductor devices.

The resulting semiconductor structure includes a plurality of semiconductor devices 110-1 through 110-N, comprising a first semiconductor device 110-1 and a second semiconductor device 110-N. The resulting semiconductor structure may further include a first contact 210 contacting: (i) the first semiconductor device 110-1 and (ii) the second semiconductor device 110-N. The resulting semiconductor structure may further include a second contact 410-1 contacting the first semiconductor device 110-1. The resulting semiconductor structure may further include a third contact 410-N contacting the second semiconductor device 110-N.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a plurality of semiconductor devices, comprising a first semiconductor device and a second semiconductor device;
a first contact contacting: (i) the first semiconductor device and (ii) the second semiconductor device;
a second contact contacting the first semiconductor device; and
a third contact contacting the second semiconductor device.

2. The semiconductor structure of claim 1, further comprising a power delivery network electrically connected to: (i) the second contact and (ii) the third contact.

3. The semiconductor structure of claim 1, further comprising:
a first power delivery network electrically connected to the second contact; and
a second power delivery network electrically connected to the third contact.

4. The semiconductor structure of claim 2, wherein the second contact contacts the first semiconductor device in a first direction; and
the third contact contacts the second semiconductor device in the first direction.

5. The semiconductor structure of claim 4, wherein the first contact contacts the first semiconductor device and the second semiconductor device in a second direction.

6. The semiconductor structure of claim 1, wherein the second contact and the third contact are each backside contacts.

7. The semiconductor structure of claim 1, wherein the first contact is a frontside contact.

8. The semiconductor structure of claim 1, wherein the second contact and the third contact are each frontside contacts.

9. The semiconductor structure of claim 1, wherein the first contact is a backside contact.

10. The semiconductor structure of claim 1, wherein the first contact is electrically connected to a third semiconductor device through a power rail.

11. The semiconductor structure of claim 2, wherein:
the second semiconductor device is in an off state; and
electric current passes from the power delivery network, through the third contact, the second semiconductor device, and the first contact, to the first semiconductor device.

12. The semiconductor structure of claim 11, wherein electric current passes from the power delivery network, through the second contact, to the first semiconductor device.

13. A method of forming a semiconductor structure, the method comprising:
forming a plurality of semiconductor devices, comprising a first semiconductor device and a second semiconductor device;
forming a first contact, wherein the first contact contacts: (i) the first semiconductor device and (ii) the second semiconductor device; and
forming a second contact and a third contact, wherein the second contact contacts the first semiconductor device and the third contact contacts the second semiconductor device.

14. The method of claim 13, further comprising:
forming a backside back end of line (BEOL) interconnect.

15. The method of claim 13, further comprising:
forming a frontside middle of line (MOL) and back end of line (BEOL) interconnect.

16. The method of claim 13, further comprising flipping the semiconductor structure subsequent to forming the first contact and prior to forming the second contact and the third contact.

17. The method of claim 13, further comprising flipping the semiconductor structure subsequent to forming the second contact and the third contact and prior to forming the first contact.

18. A method comprising:
providing a semiconductor structure comprising:
a plurality of semiconductor devices;
a first contact contacting each of the plurality of semiconductor devices;
a second contact contacting a first semiconductor device of the plurality of semiconductor devices; and
a third contact contacting a second semiconductor device of the plurality of semiconductor devices; and
providing, by a power delivery network, electric current through the second contact and the third contact.

19. The method of claim 18, further comprising:
providing additional electric current to the second semiconductor device by placing the first semiconductor device in an off state such that electric current passes through the first semiconductor device and the first contact from the second contact.

20. The method of claim 18, further comprising:
providing additional electric current to the first semiconductor device by placing the second semiconductor device in an off state such that electric current passes through the second semiconductor device and the first contact from the third contact.
